(19) United States
(12) Patent Application Publication
(10) Pub. No.: US 2023/0307308 A1
(43) Pub. Date: Sep. 28, 2023

(54) SEMICONDUCTOR STRUCTURE AND FORMING METHOD THEREOF

(71) Applicant: CHANGXIN MEMORY TECHNOLOGIES, INC., Hefei City (CN)

(72) Inventors: Qing LUO, Hefei City (CN); Taoyan YAN, Hefei City (CN)

(21) Appl. No.: 17/806,571

(22) Filed: Jun. 13, 2022

Related U.S. Application Data
(63) Continuation of application No. PCT/CN2022/086728, filed on Apr. 14, 2022.

(30) Foreign Application Priority Data
Mar. 25, 2022 (CN) 202210306382.5

(51) Int. Cl. H01L 23/31; H01L 23/29; H01L 21/02

(52) U.S. Cl. CPC H01L 23/3192; H01L 23/291; H01L 23/3171; H01L 21/02236; H01L 21/02247

(57) ABSTRACT

Embodiments of the present disclosure relate to the field of semiconductors, and provide a semiconductor structure and a forming method thereof. The forming method includes: providing a substrate; performing first oxidation on a part of the substrate to form a first dielectric layer; and performing second oxidation on a part of the substrate just under the first dielectric layer to form a second dielectric layer, where the first dielectric layer and the second dielectric layer form a dielectric layer on the substrate; and an oxidation rate of the first oxidation to a substrate material is less than that of the second oxidation to the substrate material.

### CROSS-REFERENCE TO RELATED APPLICATIONS

The present disclosure is a continuation application of International Patent Application No. PCT/CN2022/086728, filed on Apr. 14, 2022, which claims the priority to Chinese Patent Application No. 202210306382.5, titled “SEMICONDUCTOR STRUCTURE AND FORMING METHOD THEREOF” and filed with the China National Intellectual Property Administration (CNIPA) on Mar. 25, 2022. The entire contents of International Patent Application No. PCT/CN2022/086728 and Chinese Patent Application No. 202210306382.5 are incorporated herein by reference.

### TECHNICAL FIELD

Embodiments of the present disclosure relate to the field of semiconductors, and in particular to a semiconductor structure and a forming method thereof.

### BACKGROUND

In the manufacturing process of semiconductors, the dielectric layer is usually used to implement electrical isolation. The performance of the dielectric layer affects electrical properties and reliabilities of semiconductor structures. Moreover, with the continuous miniaturization of critical dimensions (CDs) of the semiconductor structures, the dielectric layer is required to be increasingly thin.

Presently, the growth of the thinner dielectric layer can hardly be implemented by the conventional method. The thickness of the dielectric layer varies depending on a position of the dielectric layer on the silicon wafer. Defects may also occur on contact interfaces between the dielectric layer and other film layers. For example, a gate oxide layer having poor thickness uniformity or defects will affect a threshold voltage of the semiconductor device, which lowers the performance of the semiconductor structure. Therefore, formation of the dielectric layer with a controllable thickness and desirable film quality is a problem to be solved urgently.

### SUMMARY

According to an aspect, an embodiment of the present disclosure provides a semiconductor structure, including: a substrate and a dielectric layer on the substrate, where the dielectric layer includes a first dielectric layer and a second dielectric layer, the second dielectric layer is located on a surface of the substrate, and the first dielectric layer is located on a surface of the second dielectric layer; and the first dielectric layer and the second dielectric layer are manufactured by different oxidation processes.

According to another aspect, an embodiment of the present disclosure provides a forming method of a semiconductor structure, including: providing a substrate; performing first oxidation on a part of the substrate to form a first dielectric layer; and performing second oxidation on a part of the substrate just under the first dielectric layer to form a second dielectric layer, where the first dielectric layer and the second dielectric layer form a dielectric layer on the substrate; and an oxidation rate of the first oxidation to a substrate material is less than that of the second oxidation to the substrate material.

### BRIEF DESCRIPTION OF THE DRAWINGS

One or more embodiments are exemplified by corresponding drawings, and these exemplified descriptions do not constitute a limitation on the embodiments. The drawings are not limited by scale unless otherwise specified. One or more embodiments are described illustratively by use of corresponding drawings. The illustrative description does not constitute any limitation on the embodiments. Unless otherwise expressly specified, the drawings do not constitute a scale limitation. To describe the technical solutions in the embodiments of the present disclosure or in the prior art more clearly, the following outlines the drawings to be used in the embodiments of the present disclosure. Apparently, the drawings outlined below are merely some embodiments of the present disclosure. Those of ordinary skill in the art may derive other drawings from the outlined drawings without any creative effort.

FIG. 1 to FIG. 4 are schematic structural diagrams corresponding to various steps in a forming method of a semiconductor structure according to an embodiment of the present disclosure.

### DETAILED DESCRIPTION

Embodiments of the present disclosure provide a semiconductor structure and a forming method thereof. In the forming method, first oxidation with a slow rate is performed to form a first dielectric layer with a certain thickness on a surface of a substrate. Second oxidation is then performed on the substrate under the first dielectric layer to form a second dielectric layer. The oxidation rate of the second oxidation to the substrate material is reduced. With the slow oxidation rate to the substrate material, the first dielectric layer and the second dielectric layer yield the controllable film thickness, and thus the thin first dielectric layer and the thin second dielectric layer are formed better. On the other hand, with the slow oxidation rate to the substrate material, the recombination rate between reactive ions and chemical bonds of the substrate material can be improved, the density of dangling bonds in the interface state between the first dielectric layer and the substrate is reduced, and there are fewer interface state defects between the first dielectric layer and the substrate. Therefore, the forming method achieves the more controllable film thickness of the dielectric layer formed by the first dielectric layer and the second dielectric layer, and reduces the interface state defects between the dielectric layer and the substrate.

The embodiments of the present disclosure are described in detail below with reference to the drawings. However, those skilled in the art may understand that in each embodiment of the present disclosure, many technical details are proposed to help readers better understand the embodiments of the present disclosure. However, the technical solutions claimed in the embodiments of the present disclosure can still be implemented based on variations and modifications of the following embodiments even without the technical details.

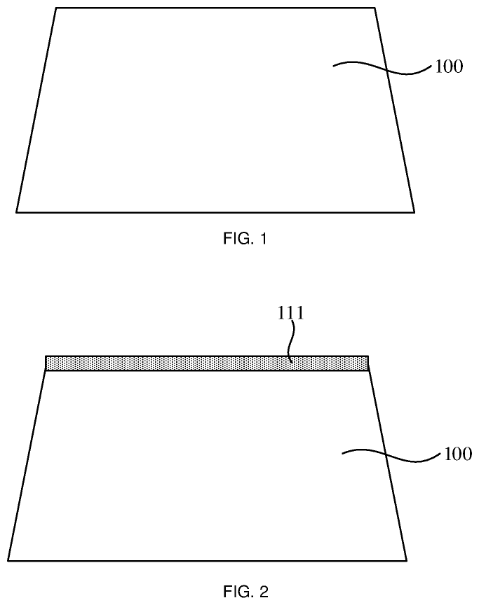

FIG. 1 to FIG. 4 are schematic structural diagrams corresponding to various steps in a forming method of a semiconductor structure according to an embodiment of the present disclosure.

Referring to FIG. 1 to FIG. 3, the forming method of a semiconductor structure includes: provide a substrate 100; perform first oxidation on a part of the substrate 100 to form a first dielectric layer 111; and perform second oxidation on a part of the substrate 100 just under the first dielectric layer 111 to form a second dielectric layer 112, where the first dielectric layer 111 and the second dielectric layer 112 form a dielectric layer 110 on the substrate 100; and an oxidation rate of the first oxidation to a substrate 100 material is less than that of the second oxidation to the substrate 100 material.

The first dielectric layer 111 formed by performing the first oxidation on the substrate 100 can reduce the oxidation rate of the second oxidation to the substrate 100 material, which lies in: The gas used in the second oxidation cannot contact and react with the substrate 100 material until it passes through the first dielectric layer 111 with the certain thickness. With the first dielectric layer 111, kinetic energy that the reactant reaches a surface of the substrate 100 in the second oxidation is reduced, so there is the reduced oxidation rate of the second oxidation to the substrate 100. Moreover, in case of the oxidation having a fast oxidation rate to the substrate 100 material, many products cannot be uniformly grown on the surface of the substrate 100 to affect the film thickness uniformity of the dielectric layer 110. On the other hand, the recombination rate between reactive ions and chemical bonds in the substrate 100 material is reduced, such that many unsaturated dangling bonds are generated in an interface state between the dielectric layer 110 and the substrate 100, and the unsaturated dangling bonds adsorb impurity ions to cause more interface state defects between the dielectric layer 110 and the substrate 100, thereby affecting the quality of the dielectric layer 110. However, the oxidation having a slow oxidation rate to the substrate 100 material can be effective to control the thickness of the dielectric layer 110 by controlling reaction time, and favorable to form the thin dielectric layer 110.

In some embodiments, the step of performing first oxidation may include: Place the substrate 100 into a chamber of the first oxidation, and perform the first oxidation on the substrate 100. With the first oxidation, the first dielectric layer 111 with a certain thickness is formed on the substrate 100. In subsequent formation of the second dielectric layer 112, the first dielectric layer 111 can reduce the oxidation rate of the second oxidation to the substrate 100 material, thereby improving the thickness uniformity of the second dielectric layer 112 and reducing the interface state defects between the second dielectric layer 112 and the substrate 100.

In some embodiments, a gas used in the first oxidation includes N₂O and a first carrier gas. For O₂ and N₂O in a same concentration, the N₂O has a lower proportion of oxygen atoms. When the first oxidation is performed on the substrate 100, the N₂O generates a lower concentration of gas-phase active free radicals (atomic oxygen) than the O₂ in the same concentration. Since the gas-phase active free radicals (atomic oxygen) serve as main reactants in an oxidation reaction, the first oxidation in which the N₂O participates has the slow oxidation rate to the substrate 100 material. The slow oxidation rate to the substrate 100 material is favorable to improve the thickness uniformity and compactness of the first dielectric layer 111, and form the thin first dielectric layer 111.

In some embodiments, a flow rate of the N₂O in the first oxidation may be 10-30 slm. The flow rate of the N₂O is associated with the oxidation rate of the first oxidation to the substrate 100 material. In case of a small flow rate of the N₂O, the oxidation rate to the substrate 100 material can be reduced. However, the first oxidation is often performed at a relatively high temperature, and in order to maintain the high temperature, the device in the first oxidation provides heat for the chamber of the first oxidation with the consumption of electricity. Therefore, the excessively slow oxidation rate to the substrate 100 material leads to a waste of time and electricity. On the other hand, in case of a large flow rate of the N₂O, the N₂O charged to the chamber may not participate in the reaction completely and the unreacted N₂O is exhausted to waste the reactive gas and increase the manufacturing cost. Therefore, by controlling the flow rate of the N₂O at 10-30 slm, the formed first dielectric layer 111 has the desirable quality, and the reactive gas and electrical energy can be utilized reasonably to reduce the waste and the production cost. In an example, the flow rate of the N₂O may be 15 slm, 20 slm or 25 slm.

In some embodiments, a temperature of the first oxidation may be 900-1,150° C. In case of a low temperature, the reactive gas participating in the first oxidation may not be reacted completely to cause a waste of the reactive gas. In case of a high temperature, neither the oxidation rate of the first oxidation to the substrate 100 material nor the quality of the first dielectric layer 111 is affected. However, in order to maintain the high temperature, the device consumes more electricity to provide the heat for the chamber of the first oxidation to waste the electrical energy and increase the manufacturing cost. Therefore, by controlling the temperature of the first oxidation at 900-1,150° C., the reactive gas is utilized reasonably, the waste of electrical energy is prevented and the manufacturing cost is reduced. In an example, the temperature of the first oxidation may be 950° C., 980° C. or 1,000° C.

In some embodiments, a duration of the first oxidation may be 10-120 s. In case of a short duration of the first oxidation, the first dielectric layer 111 will be too thin to reduce the oxidation rate of the second oxidation to the substrate 100 material effectively. In case of a long duration of the first oxidation, the first dielectric layer 111 will be too thick, such that the oxidation rate of the second oxidation to the substrate 100 material is affected and the duration for forming the dielectric layer 110 is increased. In addition, a large overall thickness of the first dielectric layer 111 and the second dielectric layer 112 is unfavorable to miniaturize the semiconductor structure. Upon formation of the second dielectric layer 112, an additional process may be provided to remove a part of the first dielectric layer 111, which makes the formation of the dielectric layer 110 complicated. Therefore, by controlling the duration of the first oxidation at 10-120 s, the first dielectric layer 111 formed reduces the oxidation rate of the second oxidation to the substrate 100 material effectively, and there is no need to remove a part of the first dielectric layer 111.

In some embodiments, a thickness of the first dielectric layer 111 may be 10-20 A. By controlling the flow rate of the reactive gas, the temperature and the duration in the first oxidation, the first dielectric layer 111 having the thickness of 10-20 A is formed. In this way, the oxidation rate of the second oxidation to the substrate 100 material can be reduced effectively. On the other hand, the large size of the semiconductor structure arising from the thick first dielectric layer 111 is prevented, and there is no need to remove the thick first dielectric layer 111. Therefore, the first dielectric layer 111 having the thickness of 10-20 A is favorable to reduce the oxidation rate of the second oxidation to the substrate 100 material effectively, without removing the thick first dielectric layer 111. It is to be understood that in other embodiments, the thickness of the first dielectric layer 111 may also be greater than 20 A, provided that the subsequent second oxidation can be performed smoothly, and the thickness of the formed dielectric layer 110 is suitable for the overall layout of the semiconductor structure.

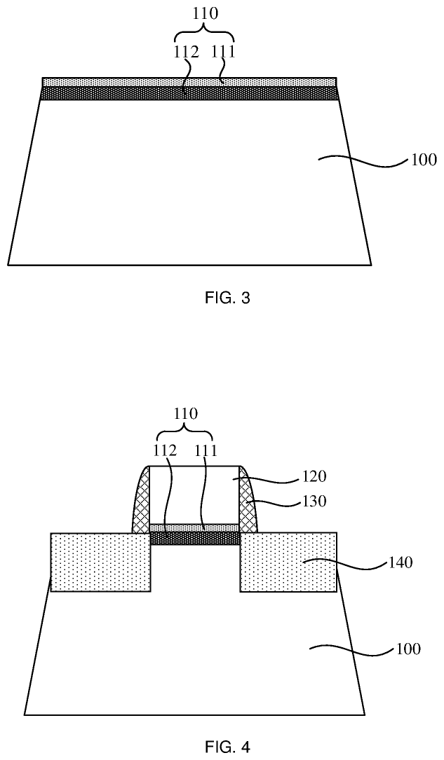

Referring to FIG. 3, in some embodiments, the step of performing second oxidation may include: Place the substrate 100 into a chamber of the second oxidation, and perform the second oxidation. As the first dielectric layer 111 with the certain thickness is formed on the surface of the substrate 100, the oxidation rate of the second oxidation to the substrate 100 material under blocking of the first dielectric layer 111 is reduced, thereby improving the thickness uniformity of the second dielectric layer 112, reducing the dangling bonds in the interface state between the second dielectric layer 112 and the substrate 100, preventing the high impurity concentration due to recombination between the dangling bonds and the impurity ions, and improving the stability of the semiconductor structure and the electrical properties of the semiconductor structure.

In some embodiments, a gas used in the second oxidation may include O₂ and a second carrier gas. With a reaction between the O₂ and the substrate 100 material, an oxide layer with the desirable charge driving capability and without other impurities can be formed. Due to the blocking of the first dielectric layer 111, the oxidation rate of the O₂ to the substrate 100 is reduced, and thus the oxide layer has the better thickness uniformity and there are fewer interface state defects between the oxide layer and the substrate 100.

In some embodiments, a flow rate of the O₂ in the second oxidation may be 10-30 slm. The flow rate of the O₂ is associated with the oxidation rate of the second oxidation to the substrate 100 material. In case of a small flow rate of the O₂, the reactive gas cannot penetrate through the first dielectric layer 111 to react with the substrate 100. Meanwhile, as the second oxidation is performed at a high temperature, the chamber of the second oxidation needs to constantly consume the electrical energy to maintain the high temperature. If the flow rate of the reactant is small, the heat cannot be utilized reasonably to waste the electrical energy. In case of a large flow rate of the O₂, the O₂ charged to the chamber does not participate in the reaction completely to waste the reactive gas and increase the manufacturing cost. Or, with the large flow rate of the O₂, the oxidation rate of the second oxidation to the substrate 100 material is too fast to ensure the quality of the second dielectric layer 112. Therefore, by controlling the flow rate of the O₂ at 10-30 slm, the formed second dielectric layer 112 has the desirable quality, and both the reactive gas and the electrical energy are not wasted. In an example, the flow rate of the O₂ may be 15 slm, 20 slm or 25 slm.

In some embodiments, a temperature of the second oxidation may be 800-1,100° C. In case of a low temperature, the gas participating in the second oxidation may not be reacted completely to cause a waste of the reactive gas. In case of a high temperature, neither the oxidation rate of the second oxidation to the substrate 100 material nor the quality of the second dielectric layer 112 is affected. However, in order to maintain the high temperature, there will be a waste of the electrical energy and an increase of the manufacturing cost. Therefore, by controlling the temperature of the second oxidation at 800-1,100° C., the reactive gas is utilized reasonably, the electrical energy is not wasted and the manufacturing cost is reduced. In an example, the temperature of the second oxidation may be 850° C., 900° C. or 950° C.

In some embodiments, a temperature of the second oxidation is lower than that of the first oxidation. The oxidation rate of the second oxidation to the substrate 100 is faster than that of the first oxidation to the substrate 100, indicating that the second oxidation is performed more easily. By properly lowering the temperature of the second oxidation, the oxidation rate of the second oxidation to the substrate 100 material can be reduced, which is favorable to form the second dielectric layer 112 with better film thickness uniformity and fewer interface state defects with the substrate 100. It is to be understood that in other embodiments, the temperature of the first oxidation may also be the same as or slightly higher than that of the second oxidation, provided that the formed second dielectric layer 112 has the desirable quality.

In some embodiments, a duration of the second oxidation may be 5-80 s. In order to form the second dielectric layer on the substrate 100 under the blocking of the first dielectric layer 111 in the second oxidation, the duration of the second oxidation cannot be too short. In case of a short duration, the reactant in the second oxidation cannot reach the surface of the substrate 100 material and thus the second dielectric layer 112 cannot be formed. Meanwhile, the dielectric layer 110 formed by the thin second dielectric layer 112 and the first dielectric layer 111 tends to show the properties of the thick first dielectric layer 111. Consequently, the desirable charge driving capability of the second dielectric layer 112 cannot be utilized effectively. In case of a long duration of the second oxidation, the formed second dielectric layer 112 is thick, such that the overall thickness of the first dielectric layer 111 and the second dielectric layer 112 is too large to miniaturize the semiconductor structure. Or even, there is an additional process to remove a part of the dielectric layer 110 to make the formation of the dielectric layer 110 complicated. Therefore, by controlling the duration of the second oxidation at 5-80 s, the second dielectric layer 112 with a certain thickness and a strong charge driving capability is formed, and there is no need to remove a part of the dielectric layer 110.

In some embodiments, a thickness of the second dielectric layer 112 may be 15-30 A, to achieve the desirable charge driving capability of the dielectric layer 110.

In some embodiments, a duration of the first oxidation is longer than that of the second oxidation. In order to achieve the desirable impurity blocking capability and charge driving capability of the dielectric layer 110, there is a balance between the thickness of the first dielectric layer 111 and the thickness of the second dielectric layer 112. However, as the oxidation rate of the second oxidation to the substrate 100 material is fast, and even under the blocking of the first dielectric layer 111, the oxidation rate of the second oxidation to the substrate 100 material is still faster than that of the first oxidation to the substrate 100 material. Therefore, the duration of the first oxidation may be longer than that of the second oxidation, thereby forming the dielectric layer 110 with the desirable impurity blocking capability and charge driving capability and improving the electrical properties and reliability of the semiconductor structure. It is to be understood that in other embodiments, the duration of the first oxidation may also be the same as or slightly shorter than that of the second oxidation, provided that the formed dielectric layer 110 has the desirable impurity blocking capability.

In some embodiments, both the first carrier gas and the second carrier gas may include H₂. The H₂ can catalyze an oxidation reaction between the N₂O and the substrate 100 material. Under the high temperature, the H₂ and the N₂O take place a chemical reaction similar to combustion to generate a great number of gas-phase active free radicals (atomic oxygen). As the atomic oxygen is strongly oxidative to the substrate 100 material, the formed first dielectric layer 111 has fewer defects and better quality. Likewise, the H₂ can further catalyze an oxidation reaction between the O₂ and the substrate 100 material. Under the high temperature, the H₂ and the O₂ take place a chemical reaction similar to combustion to generate a great number of gas-phase active free radicals (atomic oxygen). As the atomic oxygen is strongly oxidative to the substrate 100 material, the formed second dielectric layer 112 has fewer defects and better quality.

In some embodiments, a flow rate of the first carrier gas is 2-15 slm, and a flow rate of the second carrier gas is 0.15-10 slm. In case of a small flow rate of the H₂, the reaction between the N₂O and the substrate 100 material can be catalyzed. If the flow rate of the H₂ is beyond a limit, the growth rate of the first dielectric layer 111 is not increased, but there is a waste of the H₂. Likewise, in case of the small flow rate of the H₂, the reaction between the O₂ and the substrate 100 material can be catalyzed. Meanwhile, if the flow rate of the H₂ is beyond a limit in the second oxidation of the H₂ and the O₂ on the substrate 100 material, the growth rate of the second dielectric layer 112 is still not increased. In view of high flammability of the H₂, there are certain potential safety hazards for reaction products having a high content of the H₂ in tail gas treatment. Therefore, by controlling the flow rate of the first carrier gas at 2-15 slm, and the flow rate of the second carrier gas at 0.15-10 slm, there is no waste of the H₂ to reduce the potential safety hazards.

In some embodiments, a flow rate of the second carrier gas is less than that of the first carrier gas. The reactive gas in the first oxidation includes the N₂O, and the reactive gas in the second oxidation includes the O₂. In the oxidation to the substrate 100 material, the N₂O generates a lower concentration of active free radicals (atomic oxygen) than the O₂ in the same flow rate. Moreover, the flow rate of the H₂ has an impact on the oxidation rate to the substrate 100 material, and a larger flow rate of the first carrier gas can enhance the oxidation rate of the N₂O to the substrate 100 material. With the flow rate of the second carrier gas less than that of the first carrier gas, the problem of the slow oxidation rate of the N₂O to the substrate 100 material due to a low content of oxygen atoms is solved.

In some embodiments, upon formation of the second dielectric layer 112, the forming method of a semiconductor structure may further include: Perform nitriding on the dielectric layer 110. With the nitriding, the dielectric layer 110 has a relatively high dielectric constant, which can effectively prevent diffusion of the impurity ions and improve the stability of the semiconductor structure.

In some embodiments, the step of performing nitriding on the dielectric layer 110 may include: Perform the nitriding in a reaction chamber. The nitriding includes: Charge N₂ to the reaction chamber. A flow rate of the N₂ is 50-400 slm, a temperature in the reaction chamber is 700-1,150° C., a pressure in the reaction chamber is 10-100 mtor, an RF power is 1,500-2,500 W, and a duration is 30-300 s.

By performing the nitriding on the dielectric layer 110 under the above conditions, the degree of nitriding of the dielectric layer 110 can be controlled accurately, which prevents the nitrogen elements from forming the interface state between the dielectric layer 110 and the substrate 100, improves the dielectric constant of the dielectric layer 110 effectively, makes the dielectric layer 110 more compact and uniform, and improves the reliability of the semiconductor structure and the electrical properties of the semiconductor structure.

Referring to FIG. 4, in some embodiments, the forming method of a semiconductor structure may further include: Remove a part of the first dielectric layer 111 to obtain the dielectric layer 110 with a small thickness and desirable film thickness uniformity to serve as a gate oxide layer, form a gate layer on a surface of the dielectric layer 110 away from the substrate 100, and remove a part of the gate layer on the dielectric layer 110 and a part of the dielectric layer 110 on the substrate 100 to obtain an independent gate 120 and the independent dielectric layer 110. The gate 120 and the dielectric layer 110 form a gate structure. A spacer isolation layer is provided on a sidewall of the gate structure. The spacer isolation layer 130 can provide a blocking function for subsequent source-drain implantation, thereby preventing impurities from diffusing into the gate structure to affect the electrical properties of the semiconductor structure. In addition, active regions 140 may be formed in the substrate 100. When the semiconductor structure is a P-channel metal oxide semiconductor (PMOS) device, P-type doping is performed on the active regions 140. When the semiconductor structure is an N-channel metal oxide semiconductor (NMOS) device, N-type doping is performed on the active regions 140.

According to the forming method of a semiconductor structure provided by the above embodiment, the first oxidation is performed on the substrate 100 to form the first dielectric layer 111. The second oxidation is performed under the blocking of the first dielectric layer 111 to form the second dielectric layer 112. As kinetic energy that the reactant reaches the surface of the substrate 100 in the second oxidation is reduced, there is the reduced oxidation rate of the second oxidation to the substrate 100 material. With the slow oxidation rate to the substrate 100 material, products are uniformly grown on the surface of the substrate 100 to improve the film thickness uniformity. On the other hand, there are fewer dangling bonds in the interface state between the dielectric layer 110 and the substrate 100 to prevent the phenomenon that the unsaturated dangling bonds adsorb the impurity ions to cause more defects. In addition, with the slow oxidation rate to the substrate 100 material, it is easier to control the thickness of the dielectric layer 110 and form the thin dielectric layer 110. To sum up, compared with a solution in which the second oxidation is directly performed on the substrate 100 to obtain the film layer, the forming method provided by the embodiment of the present disclosure performs the first oxidation and the second oxidation on the substrate 100 at the slow oxidation rate to form the first dielectric layer 111 and the second dielectric layer 112 with the small thickness, better film thickness uniformity and fewer impurity defects, thereby forming the dielectric layer 110 with the better film thickness uniformity, controllable thickness and better quality on the substrate 100. Therefore, the forming method is favorable to miniaturize the semiconductor structure, make the semiconductor structure more reliable and improve the electrical properties of the semiconductor structure.

Accordingly, another embodiment of the present disclosure further provides a semiconductor structure. The semiconductor structure may be formed by the forming method of a semiconductor structure provided by the above embodiment. It is to be noted that contents same as or corresponding to those in the above embodiment may refer to the detailed description on the above embodiment and will not be repeated herein.

Referring to FIG. 3, the semiconductor structure includes: a substrate 100 and a dielectric layer 110 on the substrate 100. The dielectric layer 110 includes a first dielectric layer 111 and a second dielectric layer 112. The second dielectric layer 112 is located on a surface of the substrate 100. The first dielectric layer 111 is located on a surface of the second dielectric layer 112. The first dielectric layer 111 and the second dielectric layer 112 are manufactured by different oxidation processes.

In some embodiments, the substrate 100 may be made of a material directly used to manufacture the semiconductor device. In other embodiments, the substrate 100 may also be made of silicon on the insulating substrate 100, germanium, silicon, silicon germanide, silicon carbide, gallium arsenide or sapphire. In the substrate 100, there are different active regions (not shown in the figure) that are configured to form different devices. N-type doping or P-type doping may be formed in the active regions. Ions for forming the N-type doping include arsenic ions, phosphorus ions or antimony ions. Ion for forming the P-type doping include boron ions, aluminum ions or gallium ions. An isolation structure (not shown in the figure) may further be provided in the substrate 100. With a surface exposing the substrate 100, the isolation structure is configured to isolate adjacent active regions. The isolation structure may be made of at least one of insulating materials such as silicon oxide, silicon nitride or silicon oxynitride.

The dielectric layer 110 is a film layer obtained by oxidizing the substrate 100 material. In some embodiments, the dielectric layer 110 may be located on a surface of the substrate 100 where the P-type doping is formed or on a surface of the substrate 100 where the N-type doping is formed. The dielectric layer 110 is a stacked structure formed by the first dielectric layer 111 and the second dielectric layer 112. As the oxidation process for forming the first dielectric layer 111 has a slow oxidation rate to the substrate 100 material, the first dielectric layer 111 has the desirable thickness uniformity and small film thickness. The second dielectric layer 112 is formed by an oxidation process upon formation of the first dielectric layer 111 on the surface of the substrate 100. As the oxidation process of the second dielectric layer 112 has a slow oxidation rate to the substrate 100 material, the second dielectric layer 112 is thin, there are fewer dangling bonds in the interface state between the second dielectric layer 112 and the substrate 100, and there is little difference in thickness of the first dielectric layer 111 at different positions on the surface of the substrate 100, namely the thickness uniformity is desirable. To sum up, the dielectric layer 110 formed by the first dielectric layer 111 and the second dielectric layer 112 and located on the surface of the substrate 100 has the desirable thickness uniformity, and the interface state between the dielectric layer 110 and the substrate 100 is more stable, thereby improving the reliability and electrical properties of the semiconductor structure.

In some embodiments, referring to FIG. 3, the first dielectric layer 111 may include a nitride layer, and the second dielectric layer 112 may include an oxide layer. The nitride layer has a stronger blocking capability, and can prevent impurity ions from diffusing into the oxide layer. Moreover, the nitride layer has a larger dielectric constant, and can increase the overall dielectric constant of the dielectric layer 110. For example, when the dielectric layer 110 formed by stacking the nitride layer and the oxide layer serves as a gate oxide layer, a surface of the dielectric layer 110 away from the substrate 100 may be provided with a polysilicon gate. Fluoride ions are usually implanted into the polysilicon gate, such that the fluoride ions cover the interface state defects between the polysilicon gate and the dielectric layer 110 and form covalent bonds with silicon atoms of the polysilicon gate, thereby improving lattice defects at a junction between the polysilicon gate and the dielectric layer 110. The first dielectric layer 111 located at the junction with the polysilicon gate (the nitride layer) can prevent the fluoride ions from entering the second dielectric layer 112, which reduces an impurity concentration in the second dielectric layer 112 (the oxide layer), ensures the desirable charge driving capability of the oxide layer, and improves the electrical properties of the semiconductor structure.

In addition, in some embodiments, when the dielectric layer 110 serves as the gate oxide layer, nitriding is usually performed on the gate oxide layer to increase the dielectric constant of the gate oxide layer and improve the impurity blocking capability of the gate oxide layer. With entry of nitrogen elements into the gate oxide layer, there is a greater defect concentration in the gate oxide layer. As the defect concentration on the interface between the gate oxide layer and the substrate 100 increases, the noise performance of the semiconductor structure will be affected. For some RF devices, certain requirements are imposed on the noise performance of the gate oxide layer. Therefore, the nitrogen elements should be as far away as possible from the interface between the gate oxide layer and the substrate 100. When the nitride layer serves as the first dielectric layer 111, the nitrogen elements can be prevented from entering the interface between the dielectric layer 110 and the substrate 100 during nitriding to improve the noise performance of the semiconductor structure.

In some embodiments, referring to FIG. 3, a gas for manufacturing the first dielectric layer 111 includes N₂O and a first carrier gas; a gas for manufacturing the second dielectric layer 112 includes O₂ and a second carrier gas; and both the first carrier gas and the second carrier gas include H₂. As the oxidation rate of the N₂O to the substrate 100 material is less than that of the O₂ to the substrate 100 material, the N₂O is used to form the thin first dielectric layer 111. Under the blocking of the first dielectric layer 111, the oxidation rate of the O₂ for forming the second dielectric layer 112 is reduced, and thus the oxide layer with better film quality and a stronger charge driving capability can be formed. The first dielectric layer 111 formed with the N₂O is a nitrogen oxide layer, which can prevent the impurity ions from diffusing into the oxide layer to affect the charge driving capability of the dielectric layer 110. In addition, the H₂ as the first carrier gas can catalyze an oxidation reaction between the N₂O and the substrate 100 to form the nitrogen oxide layer with fewer defects and better quality. Likewise, the H₂ as the second carrier gas can catalyze an oxidation reaction between the O₂ and the substrate 100 to form the oxide layer with fewer defects and better quality.

According to the semiconductor structure provided by the embodiment, the dielectric layer 110 on the substrate 100 includes: the second dielectric layer 112 close to the substrate 100 and the first dielectric layer 111 on the second dielectric layer 112 and away from the substrate 100. The first dielectric layer 111 and the second dielectric layer 112 are formed by oxidizing the substrate 100 material via different oxidation processes. As the oxidation processes have a slow oxidation rate to the substrate 100 material, the formed first dielectric layer 111 and second dielectric layer 112 are thin with the desirable thickness uniformity, there are fewer interface state defects between the second dielectric layer 112 and the substrate 100, and the dielectric layer 110 has the controllable film thickness, desirable thickness uniformity and desirable stability. In addition, when the first dielectric layer 111 made of the nitride layer is located on the second dielectric layer 112 made of the oxide layer, the impurity ions can be prevented from diffusing into the second dielectric layer 112 to affect the charge driving capability of the second dielectric layer 112.

Those of ordinary skill in the art can understand that the above implementations are specific embodiments for implementing the present disclosure. In practical applications, various changes may be made to the above embodiments in terms of forms and details without departing from the spirit and scope of the present disclosure. Those skilled in the art may make changes and modifications without departing from the spirit and scope of the present disclosure. Therefore, the protection scope of the present disclosure should be subject to the scope defined by the claims.

1. A semiconductor structure, comprising:
a substrate and a dielectric layer on the substrate, wherein
the dielectric layer comprises a first dielectric layer and a second dielectric layer, the second dielectric layer is located on a surface of the substrate, and the first dielectric layer is located on a surface of the second dielectric layer; and
the first dielectric layer and the second dielectric layer are manufactured by different oxidation processes.

2. The semiconductor structure according to claim 1, wherein the first dielectric layer comprises a nitride layer, and the second dielectric layer comprises an oxide layer.

3. The semiconductor structure according to claim 1, wherein a gas for manufacturing the first dielectric layer comprises N₂O and a first carrier gas; a gas for manufacturing the second dielectric layer comprises O₂ and a second carrier gas; and both the first carrier gas and the second carrier gas comprise H₂.

4. A manufacturing method of a semiconductor structure, comprising:
providing a substrate;
performing first oxidation on a part of the substrate to form a first dielectric layer; and
performing second oxidation on a part of the substrate just under the first dielectric layer to form a second dielectric layer, wherein the first dielectric layer and the second dielectric layer form a dielectric layer on the substrate; and an oxidation rate of the first oxidation to a substrate material is less than that of the second oxidation to the substrate material.

5. The manufacturing method of a semiconductor structure according to claim 4, wherein a gas used in the first oxidation comprises N₂O and a first carrier gas.

6. The manufacturing method of a semiconductor structure according to claim 5, wherein a flow rate of the N₂O in the first oxidation is 10-30 slm.

7. The manufacturing method of a semiconductor structure according to claim 5, wherein a temperature of the first oxidation is 900-1,150° C.

8. The manufacturing method of a semiconductor structure according to claim 7, wherein a duration of the first oxidation is 10-120 s.

9. The manufacturing method of a semiconductor structure according to claim 4, wherein a duration of the first oxidation is longer than that of the second oxidation.

10. The manufacturing method of a semiconductor structure according to claim 5, wherein a gas used in the second oxidation comprises O₂ and a second carrier gas.

11. The manufacturing method of a semiconductor structure according to claim 10, wherein a flow rate of the O₂ in the second oxidation is 10-30 slm.

12. The manufacturing method of a semiconductor structure according to claim 10, wherein both the first carrier gas and the second carrier gas comprise H₂.

13. The manufacturing method of a semiconductor structure according to claim 12, wherein a flow rate of the first carrier gas is 2-15 slm, and a flow rate of the second carrier gas is 0.15-10 slm.

14. The manufacturing method of a semiconductor structure according to claim 12, wherein a flow rate of the second carrier gas is less than that of the first carrier gas.

15. The manufacturing method of a semiconductor structure according to claim 10, wherein a temperature of the second oxidation is 800-1,100° C.

16. The manufacturing method of a semiconductor structure according to claim 15, wherein a duration of the second oxidation is 5-80 s.

17. The manufacturing method of a semiconductor structure according to claim 4, wherein a temperature of the second oxidation is lower than that of the first oxidation.

18. The manufacturing method of a semiconductor structure according to claim 4, wherein a thickness of the first dielectric layer is 10-20 A.

19. The manufacturing method of a semiconductor structure according to claim 4, after forming the second dielectric layer, the manufacturing method further comprises: performing nitriding on the dielectric layer.

20. The manufacturing method of a semiconductor structure according to claim 19, wherein the nitriding is performed in a reaction chamber, and the nitriding comprises: charging N₂ to the reaction chamber, wherein a flow rate of the N₂ is 50-400 slm, a temperature in the reaction chamber is 700-1,150° C., a pressure in the reaction chamber is 10-100 mtor, a radio frequency (RF) power is 1,500-2,500 W, and a duration is 30-300 s.
